(19) United States
(12) Patent Application Publication
(10) Pub. No.: US 2002/0084496 A1
(43) Pub. Date: Jul. 4, 2002

(54) Semiconductor device having resistance elements, and process for fabricating the same

(76) Inventor: Masao Chatani, Tokyo (JP)

Correspondence Address: KATTEN MUCHIN ZAVIS ROSENMAN, 575 MADISON AVENUE, NEW YORK, NY, 10022-2585, US

(21) Appl. No.: 10/037,434

(22) Filed: Jan. 3, 2002

Related U.S. Application Data
(62) Division of application No. 09/497,251, filed on Feb. 3, 2000.

(30) Foreign Application Priority Data
Feb. 5, 1999 (JP) 11-029412

(51) Int. Cl. H01L 29/76

(52) U.S. Cl. 257/379; 257/916

(57) ABSTRACT

Resistance elements having plural sheet resistances or resistance elements having different conduction types are formed on a semiconductor integrated circuit device in fewer steps. An oxide film is formed on a silicon semiconductor substrate. A poly-silicon film is formed on the silicon oxide film. A resist film is used to make poly-silicon pattern pieces 6a having an appropriate length in parallel. The widths of the pattern pieces are different. When boron is ion-implanted in two directions inclined to the substrate (at angles of 45° to the substrate surface from the upper left and the upper right), ion implanted areas are formed in both side faces of the pattern pieces. The resultant is annealed and then the impurity is diffused to be activated. This causes the formation of resistance elements having the different concentrations of the impurity, corresponding to the widths of the pattern pieces.

### BACKGROUND OF THE INVENTION

1. Field of the Invention

The present invention relates to a semiconductor device having resistance elements and a process for fabricating the same, and in particular to a semiconductor device having resistance elements which has different sheet resistances (ρs) or different conduction types on a single substrate, and a process for fabricating the same wherein said resistance elements have been formed on a single substrate in fewer steps.

2. Description of the Related Art

As a resistance element to be formed on a semiconductor integrated circuit device, there is used a technique wherein an impurity is ion-implanted to a poly-silicon film to realize a desired sheet resistance.

FIGs. 1A to 1E are sectional views showing a process for fabricating this type of conventional semiconductor device in the order of its steps. As shown in FIG. 1A, a silicon oxide film 2 is first formed as an insulating film on a silicon substrate 3. A poly-silicon film 1 is grown on the silicon oxide film 2 and then ion-implantion (a fourth dose) 4 of boron is performed onto the whole surface.

Thereafter, as shown in FIG. 1B, photolithographic technique is used to form a pattern in a photoresist film 5h. Using the photoresist film 5h as a mask, ion implantation (a sixth dose) 36 of boron is selectively performed to form boron implanted areas 38. Boron of the amount of the fourth dose and the sixth dose is implanted in the boron implanted areas 38.

As shown in FIG. 1C, photolithographic technique is used to form a pattern in a photoresist film 5i. Using the photoresist film 5i as a mask, ion implantation (a seventh dose) 37 of boron is selectively performed to form boron implanted areas 39 and boron implanted areas 40 in the surface of the poly-silicon film 1. Boron is implanted in the boron implanted areas 39 in the amount of the fourth dose and the seventh dose. Boron is implanted in the boron implanted areas 40 in the amount of the fourth dose, the sixth dose and the seventh dose.

Thereafter, as shown in FIG. 1D, photolithographic technique is used to form a pattern in a photoresist film 5j. using the photoresist film 5j as a mask, the poly-silicon film 1 is selectively etched to form a poly-silicon film 6e.

As shown in FIG. 1E, the photoresist film 5j is removed and then annealing is performed to diffuse boron in each pattern piece of the poly-silicon film 6e and activate boron. Thus, resistance elements having 4 sheet resistances (ρs), that is, a resistance element (ρs5) 13, a resistance element (ρs6) 14, a resistance element (ρs7) 15 and a resistance element (ρs8) 17 are formed, correspondingly to the boron concentrations in the respective pattern pieces of the poly-silicon film 6e.

In the same manner, the resistance element (ρs5) 13, the resistance element (ρs6) 14, the resistance element (ρs7) 15 and the resistance element (ρs8) 17 can be formed, correspondingly to the boron concentrations in the respective pattern pieces of the poly-silicon film 6e by patterning the poly-silicon film 1 into pattern pieces of the poly-silicon film 6e, and then forming photoresist films two times using photolithographic technique, and selectively ion-implanting boron into said pieces of the poly-silicon film 6e.

According to the above-mentioned prior art, however, in order to form resistance elements having 4 kinds of sheet resistances (ρs) on a semiconductor integrated circuit, it is necessary to add 2 photolithographic steps other than the step of patterning into the resistance elements. Thus, the number of necessary steps increases highly. Moreover, extra materials are used. As a result, there arises a problem that both costs and TAT (turn and around time) increase.

### SUMMARY OF THE INVENTION

An object of the present invention is to provide a semiconductor device having an resistance elements wherein resistance elements having different sheet resistances (ρs) or different conduction types has been formed in fewer steps, and a process for fabricating the same.

The semiconductor device having a resistance element according to a first aspect of the present invention comprises: a resistance element pattern having resistance elements which have different widths and formed in one direction on a semiconductor substrate through an insulating film. Sheet resistances (ρs) of the resistance elements has a correlation with the widths of the resistance elements and are different in accordance with the widths of the resistance elements.

The semiconductor device according to a second aspect of the present invention, comprises a first resistance element pattern in which resistance elements are formed in one direction and on a semiconductor substrate through an insulating film, and a second resistance element pattern in which resistance elements are arranged in the direction perpendicular to the one direction. Sheet resistances (ρs) of the respective resistance elements of the first resistance element pattern are different from sheet resistances (ρs) of the respective resistance elements of the second resistance element pattern.

The semiconductor device according to a third aspect of the present invention comprises a first resistance element pattern in which resistance elements are formed in one direction and on a semiconductor substrate through an insulating film, and a second resistance element pattern in which resistance elements are arranged in the direction perpendicular to the one direction. The conduction type of the respective resistance elements of the first resistance element pattern is different from the conduction type of the respective resistance elements of the second resistance element pattern.

The semiconductor device according to a fourth aspect of the present invention comprises a resistance element pattern in which resistance elements are formed in one direction and on a semiconductor substrate through an insulating film. The sheet resistance (ρs) of a first resistance element has, at the nearest pitch positions on both sides thereof, the resistance elements, the sheet resistance (ρs) of a second resistance element having, only at the nearest pitch position on one side thereof, the resistance element, and the sheet resistance (ρs) of a third resistance element having, at the nearest pitch positions on both sides thereof, none of the resistance elements being different from each other.

The semiconductor device according to a fifth aspect of the present invention comprises a resistance element pattern in which resistance elements are formed in one direction and on a semiconductor substrate through an insulating film. The sheet resistance (ρs) of a first resistance element has, at the nearest pitch positions on both sides thereof, the resistance elements, the sheet resistance (ρs) of a fourth resistance element having, only at the nearest pitch position on one specified side thereof, the resistance element, the sheet resistance (ρs) of a fifth resistance element having, only at the nearest pitch position on the other side opposite to the specified side, the resistance element, and the sheet resistance (ρs) of a third resistance element having, at the nearest pitch positions on both sides thereof, none of the resistance elements being different from each other.

The process for fabricating a semiconductor device having a resistance element according to the present invention comprises the steps of:

growing a poly-silicon film on an insulating substrate;

forming a pattern of a photoresist;

using the photoresist pattern as a mask to pattern the poly-silicon film by photolithographic technique and etching, thereby forming a resistance element pattern comprising plural resistance elements arranged in one direction; and

ion-implanting an impurity, in a direction perpendicular to side faces of the resistance elements and at an angle in an oblique upper direction to the substrate, into side faces of the resistance elements, in the state that the photoresist remains on the resistance elements.

In the present invention, resistance elements are formed by patterning, and subsequently in the state that the photoresist film used in the patterning into the resistance elements remains on the resistance elements, ions are implanted on the substrate from an inclined direction to introduce an impurity into side faces of the resistance elements. By performing the ion implantation in the state that the photoresist film used in the patterning into the resistance elements remains on the resistance elements in this way, the shadowing effect of the photoresist film is used to introduce an impurity selectively into the resistance elements. This allows the ion dose of the resistance elements to vary in the arrangement pattern of the resistance elements and allows the resistance elements having various sheet resistances to be formed on a semiconductor integrated circuit without an increase in any photolithographic step.

### BRIEF DESCRIPTION OF THE DRAWINGS

FIGS. 1A to 1E are sectional views showing a process for fabricating a conventional semiconductor device in the order of its steps.

FIGS. 2A to 2E are sectional views showing a process for fabricating a semiconductor device according to a first embodiment of the present invention in the order of its steps.

FIG. 3 is a plane view showing the arrangement of resistance elements of a semiconductor device according to a second embodiment of the present invention.

FIGS. 4A to 4C are sectional views taken along C-D line of FIG. 3.

FIG. 5 is a plane view showing the arrangement of the resistance elements of the semiconductor device according to the second embodiment of the present invention.

FIGS. 6A to 6C are sectional views taken along E-F line of FIG. 5.

FIG. 7 is a plane view showing the arrangement of the resistance elements of the semiconductor device according to the second embodiment of the present invention.

FIG. 8 is a plane view showing the arrangement of resistance elements of a semiconductor device according to a third embodiment of the present invention.

FIGS. 9A and 9B are sectional views taken along G-H line of FIG. 8.

FIG. 10 is a plane view showing the arrangement of the resistance elements of the semiconductor device according to the third embodiment of the present invention.

FIGS. 11A to 11C are sectional views taken along I-J line of FIG. 10.

FIG. 12 is a plane view showing the arrangement of the resistance elements of the semiconductor device according to the third embodiment of the present invention.

FIGS. 13A to 13E are sectional views showing a process for fabricating a semiconductor device according to a fourth embodiment of the present invention in the order of its steps.

FIGS. 14A to 14C are sectional views for explaining an ion-implanting angle in the present invention.

FIGS. 15A are 15E are sectional views showing a process for fabricating a semiconductor device according to a fifth embodiment of the present invention in the order of its steps.

FIGS. 16A to 16E are sectional views showing a process for fabricating a semiconductor device according to a sixth embodiment of the present invention in the order of its steps.

FIG. 17 is a plane view showing the arrangement of resistance elements of a semiconductor device according to a seventh embodiment of the present invention.

FIGS. 18A to 18C are sectional views taken along K-L line of FIG. 20.

FIG. 19 is a plane view showing the arrangement of the resistance elements of the semiconductor device according to the seventh embodiment of the present invention.

FIGS. 20A to 20C are sectional views taken along M-N line of FIG. 19.

FIG. 21 is a plane view showing the arrangement of the resistance elements of the semiconductor device according to the seventh embodiment of the present invention.

FIG. 22 is a plane view showing the arrangement of resistance elements of a semiconductor device according to an eighth embodiment of the present invention.

FIG. 23 is a plane view of the eighth embodiment.

FIG. 24 is a plane view of the eighth embodiment.

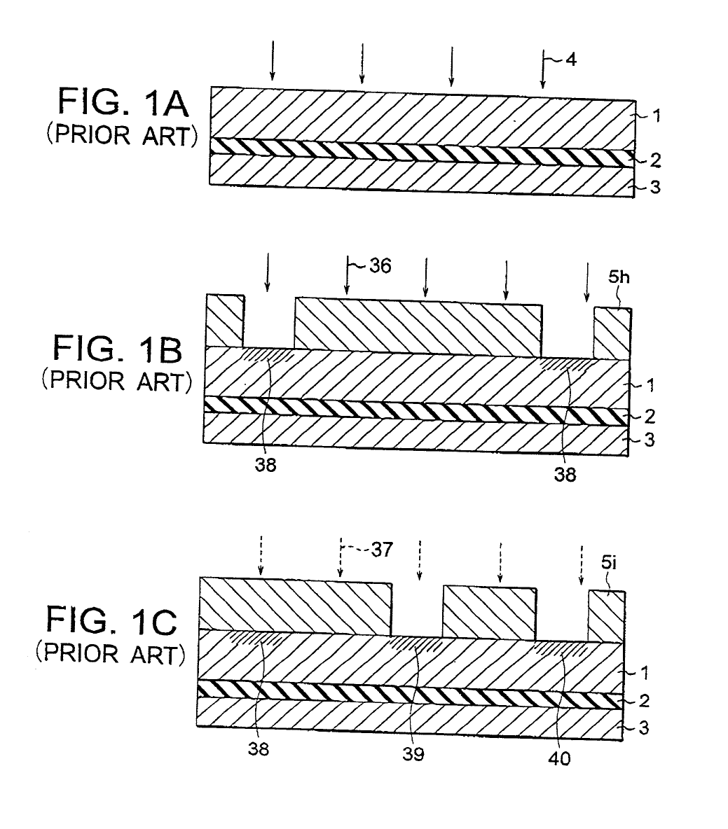

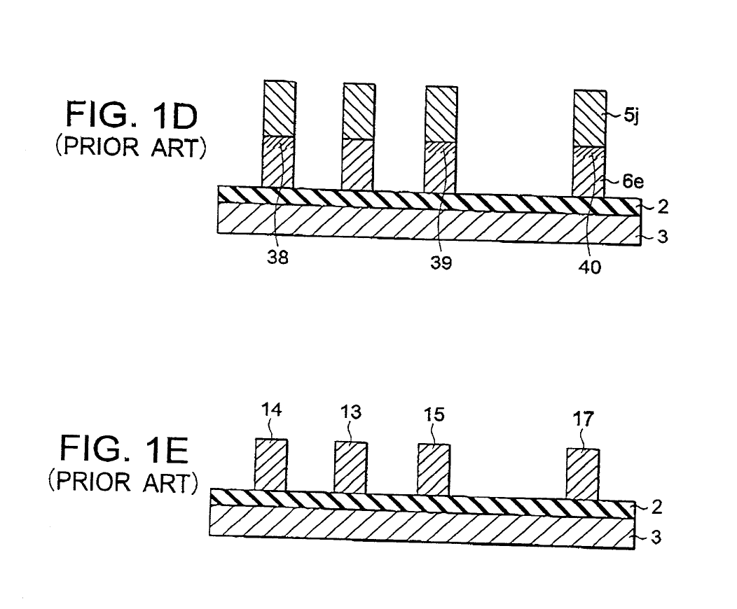

### DESCRIPTION OF PREFERRED EMBODIMENTS

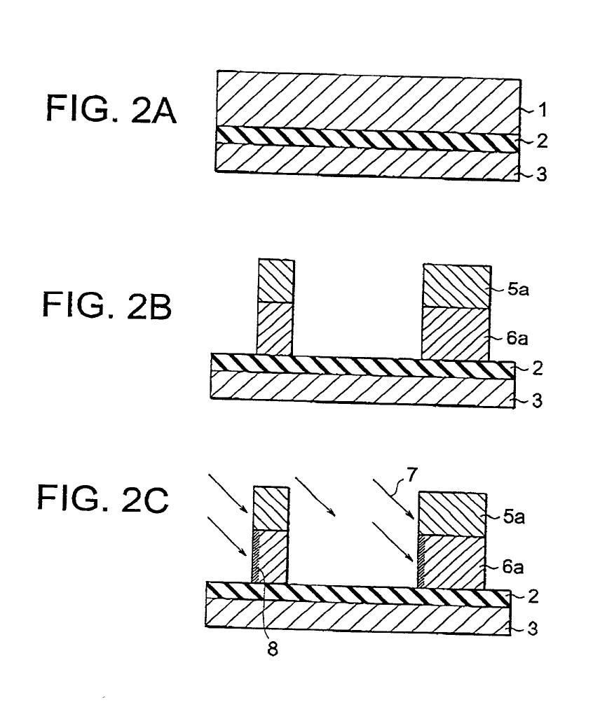

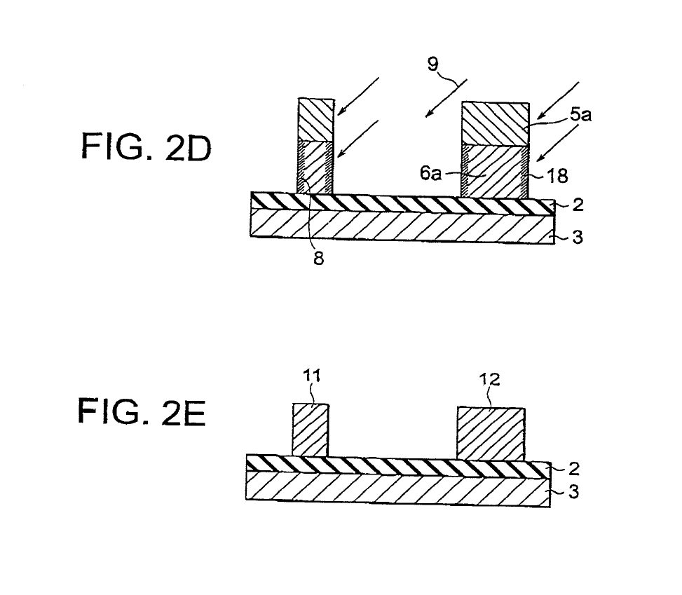

Referring to the attached drawings, preferred embodiments of the present invention will be described hereinafter. FIGS. 2A to 2E are sectional views showing a process for fabricating a first embodiment of the present invention in the order of its steps.

As shown in FIG. 2A, in the same manner as in the prior art, a silicon oxide film 2 is formed as an insulating film on a P type silicon substrate 3 so as to have a thickness of, for example, 0.1 μm. Next, a poly-silicon film 1 is grown on this silicon oxide film 2 to have a thickness of, for example, 0.8 μm. After the growth of this poly-silicon film 1, boron ions may be implanted into the whole surface.

Thereafter, as shown in FIG. 2B, a photoresist film is formed on the poly-silicon film 1 to have a thickness of, for example, 1 μm, and then this photoresist is pattered by photolithographic technique. using the resultant photoresist film 5a as a mask, the poly-silicon film 1 is selectively etched to form a pattern of a poly-silicon film 6a whose pattern pieces have different widths. Concerning the widths of the poly-silicon film 6a, for example, the width of wide pattern pieces is 2 μm and that of narrow pattern pieces is 1 μm.

As shown in FIG. 2C, after the patterning of the poly-silicon film 6a, in the state that the photoresist film 5a used for the patterning of the poly-silicon film 6a remains on the poly-silicon film 6a, boron ions are implanted thereon from the upper left side to the lower right side in this figure, for example, at an inclination angle of 45° to the surface of the silicon substrate 3 and in the direction perpendicular to the longitudinal direction of the pattern pieces of the poly-silicon film 6a, when viewed from the above. The conditions of the ion implantation are as follows: implantation energy: 30 keV, and dose: 1×10¹⁵/cm². This oblique ion implantion 7 allows the formation of ion-implanted areas 8 wherein boron is ion-implanted in a first dose in one side (the illustrated left side face) of each pattern piece of the poly-silicon film 6a.

As shown in FIG. 2D, in the state that the photoresist film 5a remains on the poly-silicon film 6a, boron ions are implanted thereon from the upper right side to the lower left side in this figure, for example, at an inclination angle of 45° to the surface of the silicon substrate 3 and in the direction perpendicular to the longitudinal direction of the pattern pieces of the poly-silicon film 6a, when viewed from the above. The conditions of the ion implantation are as follows: implantion energy: 30 keV, and dose 1×10¹⁵/cm². This ion implantion 9 allows the formation of ion-implanted areas 18 wherein boron is ion-implanted in a first dose in the other side (the illustrated right side face) of each pattern piece of the poly-silicon film 6a.

Even if in this case the widths of the pieces of the patterned poly-silicon film 6a are different form each other, as shown in FIG. 2D, the amount of boron implanted onto a unit length in the longitudinal direction of the left side face and the right side face of the narrower pattern piece of the poly-silicon film 6a is equal to the amount of boron implanted onto a unit length in the longitudinal direction of the left side face and the right side face of the wide pattern piece of the poly-silicon film 6a. This is because the areas of the side faces of all pattern pieces of the poly-silicon film 6a are the same.

Next, as shown in FIG. 2E, the photoresist film 5a is removed and then annealing treatment, for example, heating at 950° C. for 60 minutes, is performed to diffuse boron from the boron-implanted areas 8 and 18 into the poly-silicon film 6a. Thus, boron is activated. As a result, the boron concentration in the wide pattern pieces (width; 2 μm) of the poly-silicon film 6a becomes lower than that in the narrower pattern pieces (width; 1 μm) thereof because the volume of the former is larger than that of the latter. In the respective pattern pieces of the poly-silicon film 6a, resistance elements having 2 kinds of sheet resistances (ρs) are formed, correspondingly to the respective boron concentrations. That is, a resistance element 11 having a sheet resistance (ρs1) and a resistance element 12 having a sheet resistance (ρs2) are formed.

As described above, in the present embodiment, resistance elements having different sheet resistances can be formed on the same substrate without addition of any photoresist-step using a mask. In the present embodiment, boron ion is used as the impurity. The same effect can be however obtained by using an impurity other than boron, such as phosphorus, arsenic or antimony. only one example is each of the conduction type of the silicon substrate 3, the thickness of the silicon oxide film 2, the thickness of the poly-silicon film 1, the thickness of the photoresist, the energy of the ion implantion, the dose, the annealing condition, and the width of the resistance elements. They are not restrictive in the present invention.

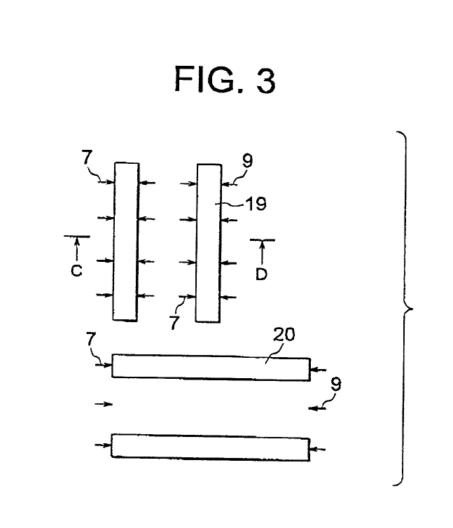

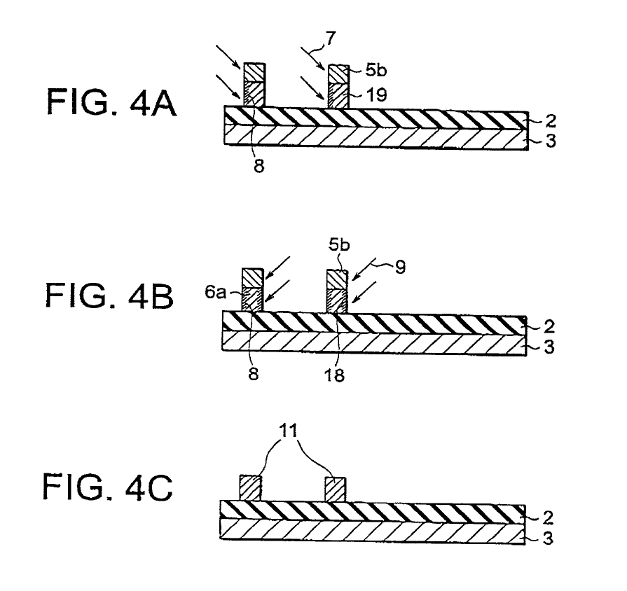

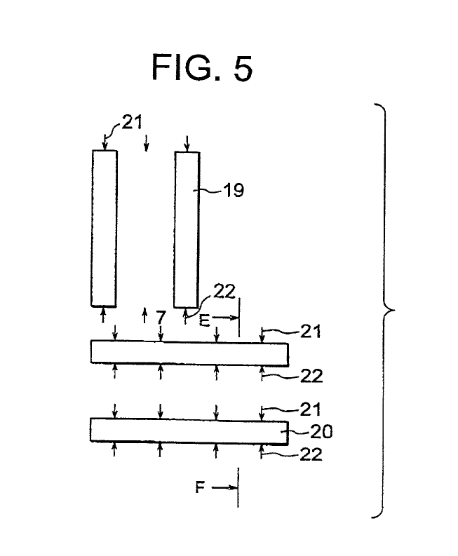

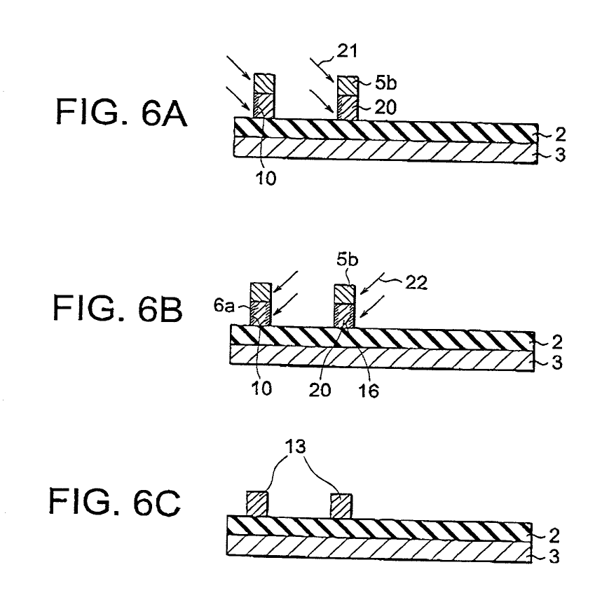

FIGS. 3 to 7 show a second embodiment of the present invention. FIGS. 3, 5 and 7 are plan views of resistance element portions, viewed from the direction perpendicular to a silicon substrate, and FIGS. 4A to 4C are sectional views taken along C-D line of FIG. 3. FIGS. 6A to 6C are sectional views taken along E-F line of FIG. 5.

A silicon oxide film 2 is formed on a silicon substrate 3. Pattern pieces of a poly-silicon film are arranged on this silicon oxide film 2. The pattern pieces of this poly-silicon film are arranged in parallel to each other and at regular intervals. Some pattern pieces 19 of the poly-silicon film are perpendicular to the other pattern pieces 20 of the poly-silicon film.

The following will describe a process for fabricating this semiconductor device. In the present embodiment, in the same way as in the first embodiment, the silicon oxide film 2 is formed as an insulating film on the silicon substrate 3, and then the poly-silicon film is grown. Thereafter, photolithographic technique is used to pattern the poly-silicon film. Thus, the first pattern pieces 19 and the second pattern pieces 20 are simultaneously formed.

AS shown in FIGS. 3 and 4A, in the same way as in the first embodiment, the poly-silicon film is patterned. Then, in the state that the mask of a photoresist film 5b used for the patterning remains on the poly-silicon film 6a, ion implantation (a first dose) 7 of boron is performed into one side face of each of the poly-silicon pattern pieces 19 in the direction perpendicular to the longitudinal direction of the pattern pieces 19 of the poly-silicon film (from the left side in this figure), when viewed from the above, and at an angle of 45° in an obliquely upper and left direction to the silicon substrate 3.

As shown in FIG. 4A, this causes the formation of boron implanted areas 8 in one side of each of the poly-silicon pattern pieces 19 of the poly-silicon film 6a. As shown in FIG. 4B, in the state that the photoresist film 5b remains on the poly-silicon, ion implantation (a first dose) 9 of boron is performed onto the other side face of each of the poly-silicon pattern pieces 19 in the direction perpendicular to the longitudinal direction of the polysilicon pattern pieces 19 (from the right side in this figure), when viewed from the above, and at an angle of 45° in an obliquely upper and right direction to the silicon substrate 3.

As shown in FIG. 4B, this causes the formation of boron implanted areas 18 in the other side of each of the poly-silicon pattern pieces 19. In this case, by both of the ion implantation, boron is implanted onto the side faces along short sides of the respective resistance elements composed of the poly-silicon pattern pieces 20 but boron is not ion-implanted onto the side faces along long sides of the respective resistance elements, as shown in FIG. 3.

As shown in FIGS. 5 and 6A, in the state that the photoresist film 5b remains on the poly-silicon 6a, ion implantation (a second dose) 21 of boron is performed onto one side face of each of the poly-silicon pattern pieces 20 in the direction perpendicular to the longitudinal direction of the poly-silicon pattern pieces 20, when viewed from the above, and at an angle of 45° in an obliquely upper and left direction to the silicon substrate 3.

As shown in FIG. 6A, this causes the formation of boron implanted areas 10 on the one side of each of the poly-silicon pattern pieces 20.

As shown in FIGS. 5 and 6B, in the state that the photoresist film 5b remains on the poly-silicon 6a, ion implantation (a second dose) 22 is performed onto the other side face of each of the poly-silicon pattern pieces 20 in the direction perpendicular to the longitudinal direction of the respective poly-silicon pattern pieces 20, when viewed from the above, and at an angle of 45° in an obliquely upper and right direction to the silicon substrate 3.

As shown in FIG. 6B, this causes the formation of born implanted areas 16 on the other side of each of the poly-silicon pattern pieces 20.

In this case, by both of the ion implantation, boron is implanted into the side faces along short sides of the respective resistance elements composed of the poly-silicon pattern pieces 19 but boron is not ion-implanted onto the side faces along long sides of the respective resistance elements, as shown in FIG. 5.

Next, as shown in FIGS. 4C, 6C and 7, the photoresist film 5b is removed and then annealing treatment is performed to diffuse boron to the inside of the poly-silicon film. Thus, boron is activated. As a result, in the poly-silicon pattern pieces 19 and the poly-silicon pattern pieces 20, resistance elements having 2 different sheet resistances (ρs1 and ρs3) are formed, correspondingly to the respective boron concentrations. That is, a resistance element 11 having a sheet resistance (ρs1) and a resistance 13 having a sheet resistance (ρs3) are formed in the poly-silicon pattern pieces 19 and the poly-silicon pattern pieces 20, respectively. Resistance elements along the same direction as the poly-silicon pattern pieces 19 are arranged have the same sheet resistance (ρs1), and resistance elements along the same direction as the poly-silicon pattern pieces 20 are arranged have the same sheet resistance (ρs3).

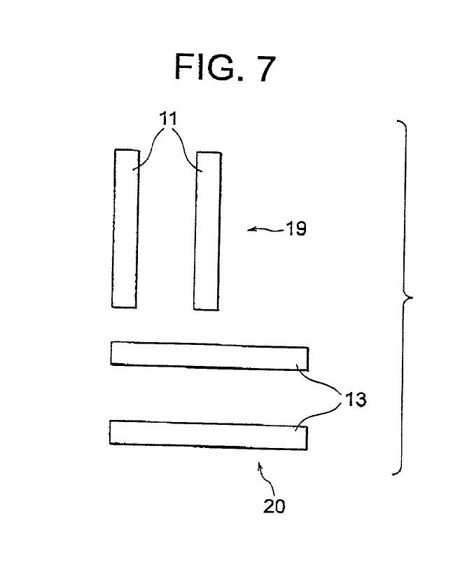

In the preset embodiment, it is possible to form the resistance elements having two kinds of sheet resistances (ρs1 and ρs3) as shown in FIG. 7, without addition of any mask, in the above-mentioned manner.

The same effect can be obtained by using phosphorus, arsenic, antimony or the like, as well as boron, as the impurity in the present embodiment.

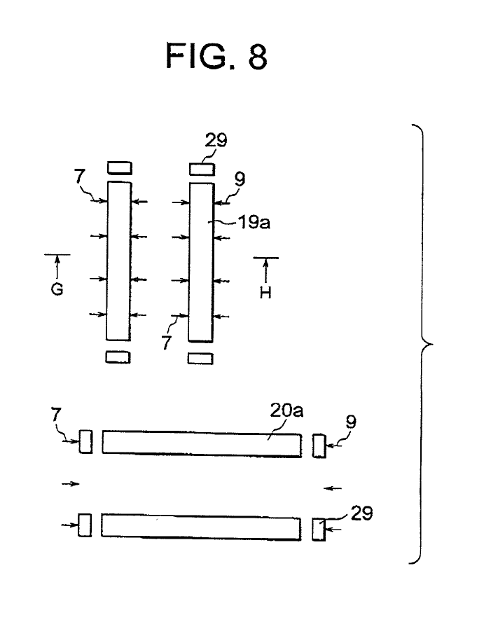

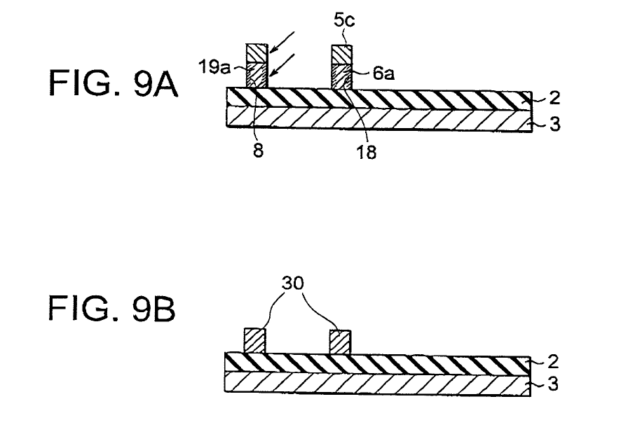

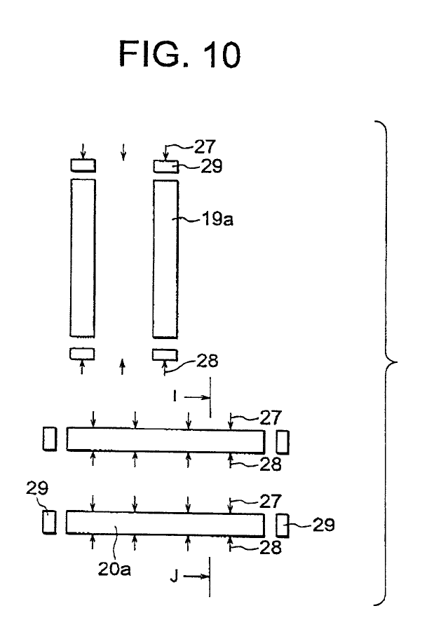

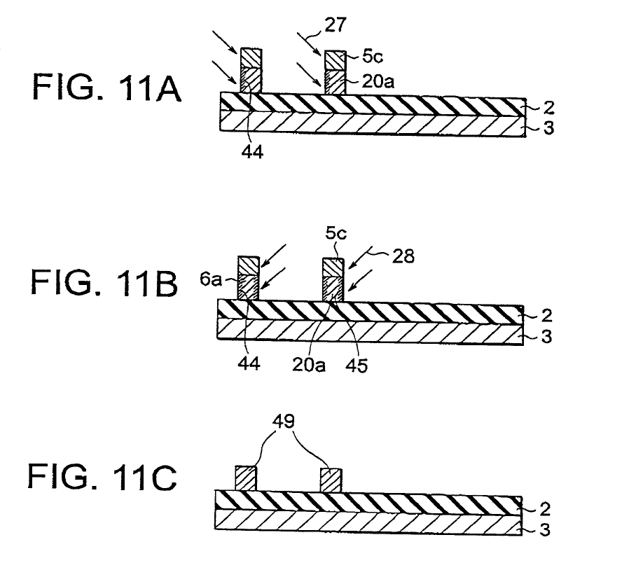

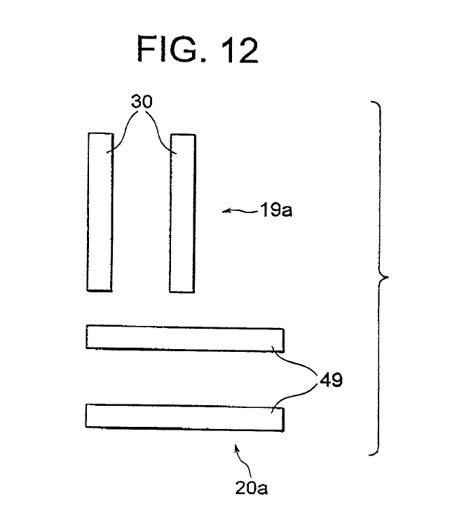

FIGS. 8 to 12 show a third embodiment of the present invention. FIGS. 8, 10 and 12 are plane views of resistance element portions, viewed from the direction perpendicular to a silicon substrate, and FIGS. 9A and 9B are sectional views taken along G-H line of FIG. 8. FIGS. 11A to 11C are sectional views taken along I-J line of FIG. 10.

A silicon oxide film 2 is formed on a silicon substrate 3. Pattern pieces 19a of a poly-silicon film 6a are arranged on this silicon oxide film 2 in the manner that the pattern pieces 19a having a constant width are arranged in parallel to each other (i.e., along one direction) and at regular intervals. Moreover, poly-silicon pattern pieces 20a of the poly-silicon film 6a are formed in the manner that the pattern pieces 20a having a constant width are perpendicular to the poly-silicon pattern pieces 19a (i.e., in parallel to each other) and at regular intervals.

A poly-silicon dummy pattern piece 29 is formed near the end (i.e., the short side) in the longitudinal direction of each of the poly-silicon pattern pieces 19a, 20a of the poly-silicon film. This poly-silicon dummy pattern piece 29 is patterned at the same time when the respective poly-silicon pattern pieces are patterned. The distance between each of the dummy pattern pieces 29 and the end (i.e., the short side) in the longitudinal direction of each of the poly-silicon pattern pieces is shorter than the distance between the resistance elements.

In the same manner as in the second embodiment, in the present invention the silicon oxide film 2 is formed as an insulating film on the silicon substrate 3, and then the poly-silicon film is grown. Thereafter, photolithographic technique is used to pattern the poly-silicon film. Thus, the poly-silicon pattern pieces 19a and the poly-silicon pattern pieces 20a are simultaneously formed. Moreover, in the present embodiment, the dummy pattern pieces 29 are formed at the same time when the poly-silicon pattern pieces 19a and the poly-silicon pattern pieces 20a are formed.

In the same manner as in the second embodiment, after patterning the poly-silicon film, in the state that a photoresist film 5c remains on the poly-silicon film, ion implantation (a first dose) 7 of boron is performed onto one side face of each of the poly-silicon pattern pieces 19a in the direction perpendicular to the longitudinal direction of the pattern pieces 19a of the poly-silicon film (from the illustrated left side), and at an angle of 45° in an obliquely upper and left direction to the silicon substrate 3, as shown in FIG. 8.

As shown in FIG. 8, ion implantation (the first dose) 9 of boron is performed onto the other side face of each of the poly-silicon pattern pieces 19a in the direction perpendicular to the longitudinal direction of the poly-silicon pattern pieces 19a (from the illustrated right side), and at an angle of 45° in an obliquely upper and right direction to the silicon substrate 3.

As shown in FIG. 9A, this causes the formation of boron implanted areas 8 and boron implanted areas 18 in both side faces along long sides of each of the poly-silicon pattern pieces 19a. However, boron ions are not implanted in both side faces along long sides of each of the poly-silicon pattern pieces 20a. Since the poly-silicon dummy pattern piece 29 is formed near the side faces along short sides of each of the poly-silicon pattern pieces 20a, in any ion implanting step, boron is not implanted in the side faces along the short sides of each of the poly-silicon pattern pieces 20a by shadowing effect of the poly-silicon dummy pattern pieces 29 and the photoresist 5c thereon.

Next, as shown in FIGS. 10 and 11A, in the state that the photoresist 5c remains on the poly-silicon film 6a, ion implantation (a third dose) 27 of arsenic ion is performed onto one side face of each of the poly-silicon pattern pieces 20a in the direction perpendicular to the longitudinal direction of the poly-silicon pattern pieces 20a (from the illustrated upper side in FIG. 10), when viewed from the above, and at an angle of 45° in an obliquely upper and left direction to the silicon substrate 3 (FIG. 11A). As shown in FIG. 11A, this causes the formation of arsenic implanted areas 44 in the one side face of each of the poly-silicon pattern pieces 20a.

Next, as shown in FIGS. 10 and 11B, in the state that the photoresist film 5c remains on the poly-silicon film 6a, ion implantation (a third dose) 28 of arsenic is performed onto the other side face of each of the poly-silicon pattern pieces 20a in the direction perpendicular to the longitudinal direction of the poly-silicon pattern pieces 20a (from the illustrated lower side in FIG. 10), when viewed from the above, and at an angle of 45° in an obliquely upper and right direction to the silicon substrate 3 (Fig. 11B). This causes the formation of arsenic implanted areas 45 in the other side face of each of the poly-silicon pattern pieces 20a.

However, arsenic is not implanted in both side faces along long sides of each of resistance elements composed of the poly-silicon pattern pieces 19a. Since the poly-silicon dummy pattern piece 29 is formed near the side faces along short sides of each of the poly-silicon pattern pieces 19a, in any ion implanting step, boron is not implanted in these side faces by the same shadowing effect of the poly-silicon dummy pattern piece 29 as described above.

Thereafter, as shown in FIGS. 9B, 11C and 12, the photoresist film 5c is removed and then annealing treatment is performed to diffuse boron and arsenic. Thus, boron and arsenic are activated. As a result, resistance elements having different conduction types and different sheet resistances (ρs) are formed correspondingly to the respective boron concentrations and arsenic concentrations in the poly-silicon pattern pieces 19a and the poly-silicon pattern pieces 20a. That is, P type resistance elements 30 having a sheet resistance (ρs1) and N type resistance elements 49 having a sheet resistance (ρs4) are formed. In this case, resistance elements along the same direction as the poly-silicon pattern pieces 19a are arranged have P type conduction type and the same sheet resistance (ρs1), and resistance elements along the same direction as the poly-silicon pattern pieces 20a are arranged have N type conduction type and the same sheet resistance (ρs4).

In the present embodiment, 2 types of resistance elements having different conduction types can be formed without addition of any photoresist-step using a mask in the manner as described above. The dummy pattern pieces 29 may be left and removed. Actual resistance values of the resistance elements 19a and 20a vary in accordance with the position of contacts against the arrangement of the respective resistance elements. The length of the resistance elements 19a may be different from that of the resistance elements 20a. In the group of the resistance elements 19a arranged along one direction, their lengths may be different. This is also true for the resistance elements 20a.

The impurities used in the present embodiment are boron and arsenic. The same effect can be however obtained by using various impurities such as phosphorus or antinomy, other than these impurities.

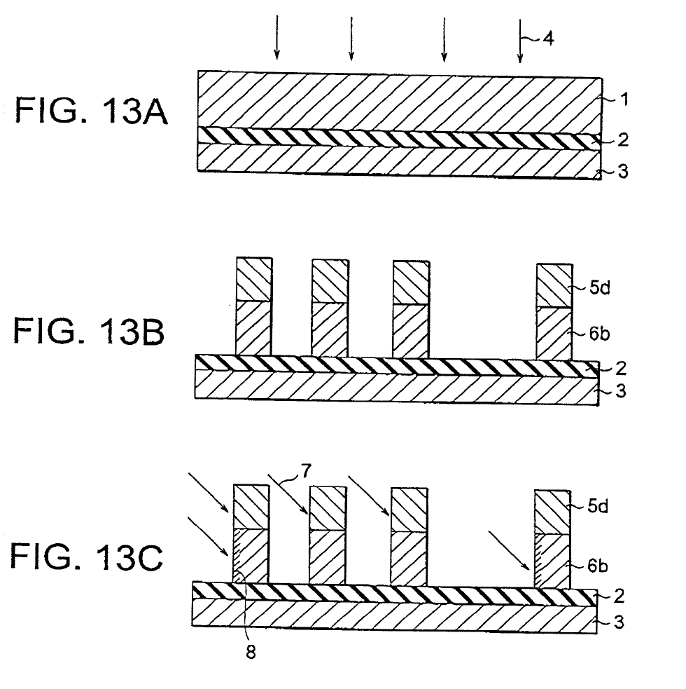

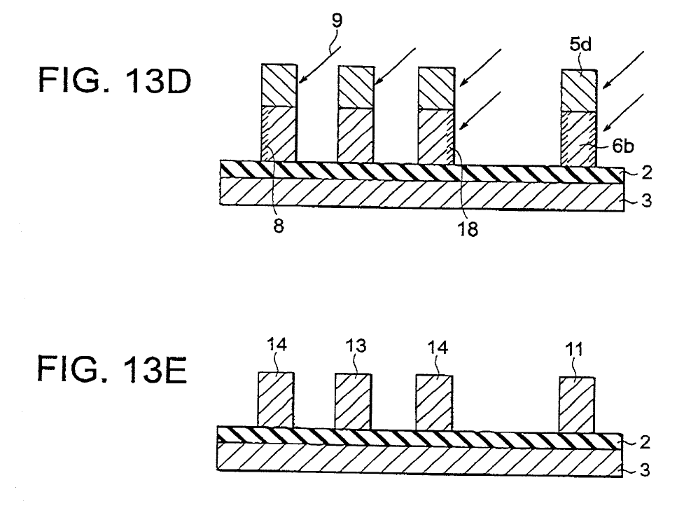

FIGS. 13A to 13E are sectional views showing a fourth embodiment of the present invention in the order of its steps. As shown in FIG. 13A, in the same manner as in the first embodiment of the present invention, a silicon oxide film 2 is formed as an insulating film on a P type silicon substrate 3 so as to have a thickness of, for example, 0.1 μm. Next, a poly-silicon film 1 is grown to have a thickness of, for example, 0.8 μm. Thereafter, ion implantion (a fourth dose) 4 of boron is performed into the whole surface of the substrate and in the direction perpendicular to the substrate. The ion implantation conditions are as follows: for example, energy: 30 keV, and dose: 1×10¹⁵/cm².

Next, as shown in FIG. 13B, photolithographic technique is used to form a photoresist film 5d. Using this as a mask, the poly-silicon film 1 is patterned to form poly-silicon pattern pieces 6b.

As shown in FIG. 13C, in the same manner as in the first embodiment, in the state that the photoresist film 5d having a thickness of 1 μm remains on the poly-silicon pattern pieces 6b after the patterning, ion implantation (a first dose) 7 of boron is performed in the direction perpendicular to the longitudinal direction of the poly-silicon film pattern pieces 6b (from the left side in FIG. 13C), when viewed from the above, and at an angle of 45° in an obliquely upper and left direction to the surface of the silicon substrate 3. The conditions of the ion implantation are as follows: implantion energy: 30 keV, and dose: 3×10¹⁵/cm².

In the case that, about the respective poly-silicon pattern pieces 6b, the pattern piece 6b has no pattern pieces at the adjacent pitch position on the left in FIG. 13, boron is ion-implanted in the left side face of the pattern piece 6b to form a boron implanted area 8. In the case that the poly-silicon pattern piece 6b has another pattern piece at the adjacent pitch position on the left in FIG. 13, born is not ion-implanted in the left side of the pattern piece 6b by shadowing effect of the photoresist 5d on the adjacent pattern piece 6b. In this case, the width of the poly-silicon pattern pieces 6b is, for example, 1 μm. The arrangement pitch of the pieces 6b is, for example, 1.8 μm. The distance between the right end piece 6b and the second piece 6b from the right end is, for example, 2.4 μm.

As shown in FIG. 13D, in the same manner as in the first embodiment, in the state that the photoresist 5d remains on the poly-silicon pattern pieces 6b, ion implantation (the first dose) 9 of boron is performed in the direction perpendicular to the longitudinal direction of the poly-silicon film pattern pieces 6b (from the right side in FIG. 13D), when viewed from the above, and at an angle of 45° in an obliquely upper and right direction to the surface of the silicon substrate 3.

Similarly to the above, in the case that, about the respective poly-silicon pattern pieces 6b, the pattern piece 6b has no pattern pieces at the adjacent pitch position on the right in FIG. 13D, boron is ion-implanted in the right side face of the pattern piece 6b to form a boron implanted area 18. In the case that the poly-silicon pattern piece 6b has another pattern piece at the adjacent pitch position on the right in FIG. 13D, born is not ion-implanted in the right side of the pattern piece 6b by shadowing effect of the photoresist 5d on the adjacent pattern piece 6b.

As described above and shown in FIGS. 13D and 13E, in the case of, for example, the right end pattern piece 6b in FIG. 13D (namely, in the case that any poly-silicon pattern piece is not present at pitch positions adjacent to both sides of the poly-silicon pattern piece 6b), boron is implanted in both side faces of the piece 6b. In the case of, for example, the second piece 6b from the right end of FIG. 13D (namely, in the case that the piece 6b has, only at the left side pitch position adjacent thereto, another piece and does not have, at the right side pitch position adjacent thereto, any piece), boron is implanted only in the right side of the piece 6b. In the case of, for example, the second piece 6b from the left end of FIG. 13D (namely, in the case that the piece 6b has, at both sides adjacent thereto, other pieces), boron is not implanted to both side faces of the piece 6b. In the case of, for example, the left end piece 6b in FIG. 13D (namely, in the case that the piece 6b has, only at the right side pitch position adjacent thereto, another piece and does not have, at the left side pitch position adjacent thereto, any piece), boron is implanted only in the left side of the piece 6b.

As shown in FIG. 13E, therefore, the photoresist film 5d is removed and then annealing treatment, for example, heating at 950° C. for 60 minutes, is performed to diffuse boron. Thus, boron is activated. As a result, resistance elements having different sheet resistances (ρs) [that is, a resistance element (ρs1) 11, a resistance element (ρs6) 14, and a resistance element (ρs5) 13] are formed, correspondingly to the respective boron concentrations in the poly-silicon pattern pieces 6b. In this case, the left end resistance element and the second resistance element from the right end, into which boron is implanted in the same dose, have the same sheet resistance (ρs6).

In the above-mentioned manner, the resistance elements having three kinds of sheet resistances within the range of a few tens Ω/□ to a few kilo-Ω/□ can be formed on the same substrate without addition of any photoresist-step. The impurity used in the present embodiment is boron. The same effect can be however obtained by using various impurities such as phosphorus or antinomy, other than boron. Similarly to the first embodiment, only one example is each of the conduction type of the silicon substrate 3, the thickness of the silicon oxide film 2, the thickness of the poly-silicon film 1, the energy of the ion implantion, the dose, the thickness of the photoresist film 5d, the width and the pitch of the poly-silicon pattern pieces 6b, the temperature and time of the annealing. They are not restrictive in the present invention. It is allowable to use any one of the resistance elements 11, 12, 13 and 14 as a dummy resistance element, and dispose this dummy resistance element only to block ion implantation (oblique ion implantation) into resistance elements adjacent thereto.

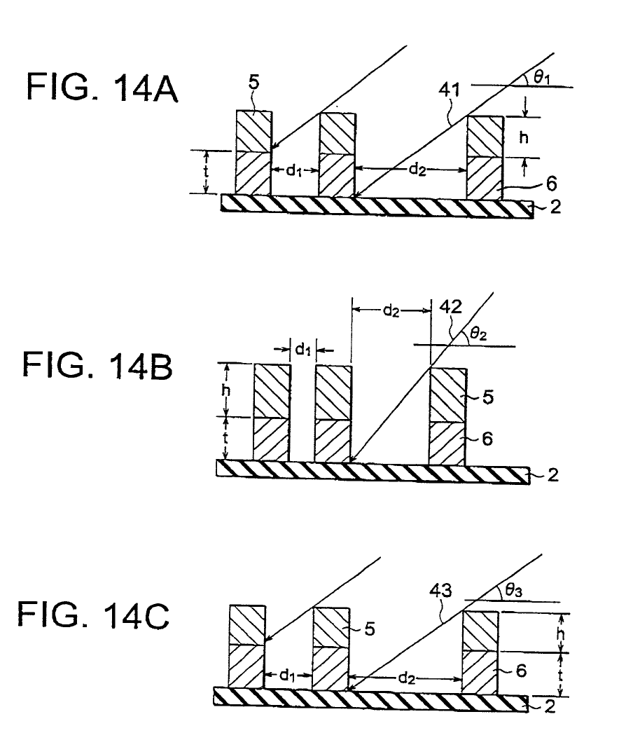

The following will describe the effect, when ion implantation is performed in the direction perpendicular to the longitudinal direction of the poly-silicon film pattern pieces and at an angle from the oblique upper to the silicon substrate, by this angle. FIGS. 14A to 14C are sectional views for explaining, when an impurity is ion-implanted at an angle from the oblique upper, this angle.

As shown in FIG. 14A, in the same manner as in the first embodiment of the present invention, a silicon oxide film 2 is formed as an insulating film on a silicon substrate. Next, a poly-silicon film is grown on the whole surface. Thereafter, photolithographic technique is used to pattern the poly-silicon, so that poly-silicon pattern pieces 6 having a given width are formed. In the case that this poly-silicon pattern pieces 6 having a constant width are arranged in parallel and at a constant pitch, it is assumed that t, h, d₁ and d₂ represent the thickness of the poly-silicon pattern pieces 6, the thickness of the photoresist, the minimum distance between the pieces 6, and a larger distance between the pieces 6, respectively. oblique ion implantation 41 of boron is performed in the direction perpendicular to the longitudinal direction (i.e., arranging direction) of the poly-silicon pattern pieces 6, when viewed from the right side in FIG. 14A, and at an angle θ₁ in the oblique upper and right direction to the silicon substrate. In this case, in order to ion-implant boron into the poly-silicon pattern pieces 6 adjacent at the distance d₂ and not to ion-implant boron into the pieces 6 adjacent at the minimum distance d₁, it is necessary to implant boron at an angle within the range represented by the following inequality 1:

h/d₁>tanθ₁>(h+t) /d₂.

In the case that the minimum distance d₁ between the pattern pieces 6 becomes small and the thickness h of the photoresist film 5 becomes large, as shown in FIG. 14B, or in the case that the thickness of the pattern pieces 6 becomes small, as shown in FIG. 14C, similar relationships are necessary. The range of implantation angles θ₂ and θ₃ are different. In this case, usually t is 1 μm or less and d₁ is 1 μm or less, but they may be above 1 μm.

By deciding the arranging pattern of the poly-silicon film and the like under such conditions, ion implantation can be performed only into desired poly-silicon pattern pieces without using any mask. In the above-mentioned respective embodiments, ion implantation is performed onto the substrate at an angle of 45°, but an appropriate implantation angle is not constant in accordance with conditions of the distance of the resistance elements, the thickness thereof, the thickness of the photoresist, and the like, as described above.

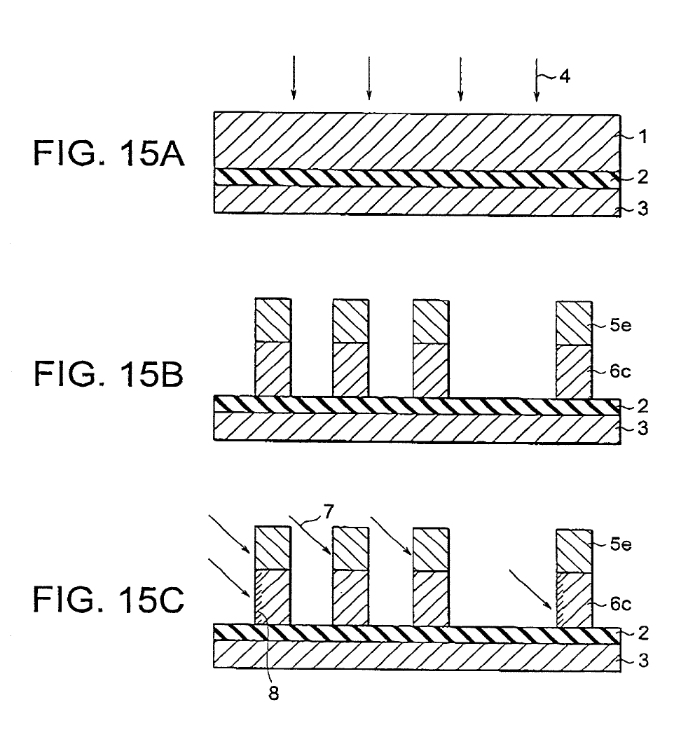

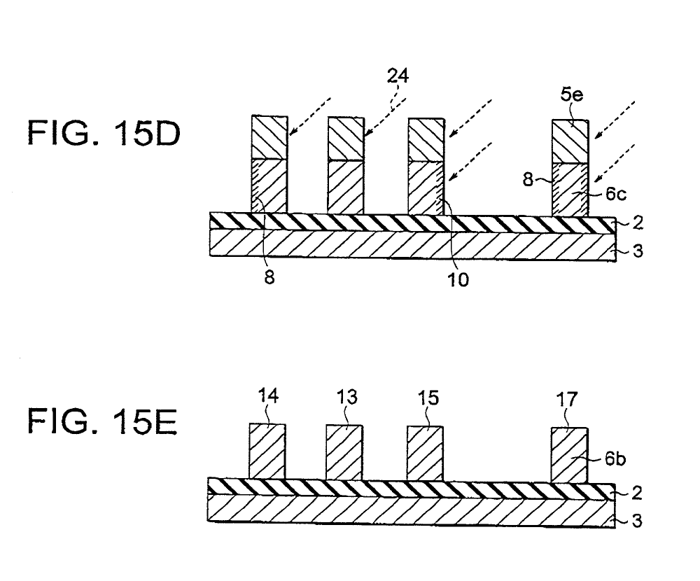

FIGS. 15A to 15E are sectional views showing a process for fabricating a semiconductor device according to a fifth embodiment of the present invention in the order of its steps. As shown in FIG. 15A, in the same manner as in the fourth embodiment, a silicon oxide film 2 is formed as an insulating film on a silicon substrate 3. Next, a poly-silicon film 1 is grown on the silicon oxide film 2. Thereafter, ion implantion (a fourth dose) 4 of boron is performed onto the whole surface. Thereafter, as shown in FIG. 15B, the poly-silicon film 1 is patterned using a photoresist film 5e, to make poly-silicon film into given pattern pieces 6c of resistance elements.

Next, as shown in FIG. 15C, in the state that the photoresist film 5e remains on the poly-silicon pattern pieces 6c, ion implantation (a first dose) 7 of boron is performed in the direction perpendicular to the longitudinal direction of the poly-silicon film pattern pieces 6c (from the left side in FIG. 15C), when viewed from the above, and at an angle of 45° in an obliquely upper and left direction to the surface of the silicon substrate 3. Thus, boron implanted areas 8 are formed in side faces of some of the poly-silicon pattern pieces 6c.

As shown in FIG. 15D, in the same manner as in the first embodiment of the present invention, in the state that the photoresist 5e remains on the poly-silicon pattern pieces 6c, ion implantation (a fourth dose, which is different from the first dose) 24 of boron is performed in the direction perpendicular to the longitudinal direction of the poly-silicon film pattern pieces 6c (from the right side in FIG. 15D), when viewed from the above, and at an angle of 45° in an obliquely upper and right direction to the surface of the silicon substrate 3.

Similarly to the above, in the case that, about the respective poly-silicon pattern pieces 6c, the pattern piece 6c has no pattern pieces at the adjacent pitch position on the right in FIG. 15D, boron is ion-implanted in the right side face of the pattern piece 6c to form a boron implanted area 10. In the case that the poly-silicon pattern piece 6c has another pattern piece at the adjacent pitch position on the right in FIG. 15D, born is not ion-implanted in the right side of the pattern piece 6c by shadowing effect of the photoresist 5e on the adjacent pattern piece 6c.

Therefore, in the case of, for example, the right end poly-silicon pattern piece 6c in FIG. 15D (namely, in the case that any poly-silicon pattern piece is not present at pitch positions adjacent to both sides of the poly-silicon pattern piece 6c), boron is implanted in the total amount of the first and fourth doses in both side faces of the piece 6b. In the case of, for example, the second piece 6c from the right end of FIG. 15D (namely, in the case that the piece 6c has, only at the left side pitch position adjacent thereto, another piece 6c and does not have, at the right side pitch position adjacent thereto, any piece), boron is implanted in the fourth dose only in the right side of the piece 6c. In the case of, for example, the second piece 6c from the left end of FIG. 15D (namely, in the case that the piece 6c has, at both sides adjacent thereto, other pieces), boron is not implanted to both side faces of the piece 6c. In the case of, for example, the left end piece 6c in FIG. 15D (namely, in the case that the piece 6c has, only at the right side pitch position adjacent thereto, another piece 6c and does not have, at the left side pitch position adjacent thereto, any piece), boron is implanted in the first dose only in the left side of the piece 6c.

Next, the photoresist film 5e is removed and then annealing treatment is performed to diffuse boron. Thus, boron is activated. As a result, as shown in FIG. 15E, resistance elements having different sheet resistances (ρs) [that is, a resistance element (ρs8) 17, a resistance element (ρs7) 15, a resistance element (ρs5) 13 and a resistance element (ρs6) 14] are formed, correspondingly to the respective boron concentrations in the poly-silicon pattern pieces. In this case, boron is implanted into the poly-silicon pattern pieces 6c in different doses from the right and left directions. Therefore, in the FIG. 15E, the sheet resistance of the left end resistance element is different from that of the second resistance element from the right end, which is different from the fourth embodiment. in the manner as described above, the resistance elements having 4 kinds of sheet resistances can be formed on the same substrate without addition of any mask. In the present embodiment, the same effect can be obtained by using impurities such as phosphorus, arsenic and antimony, as well as boron.

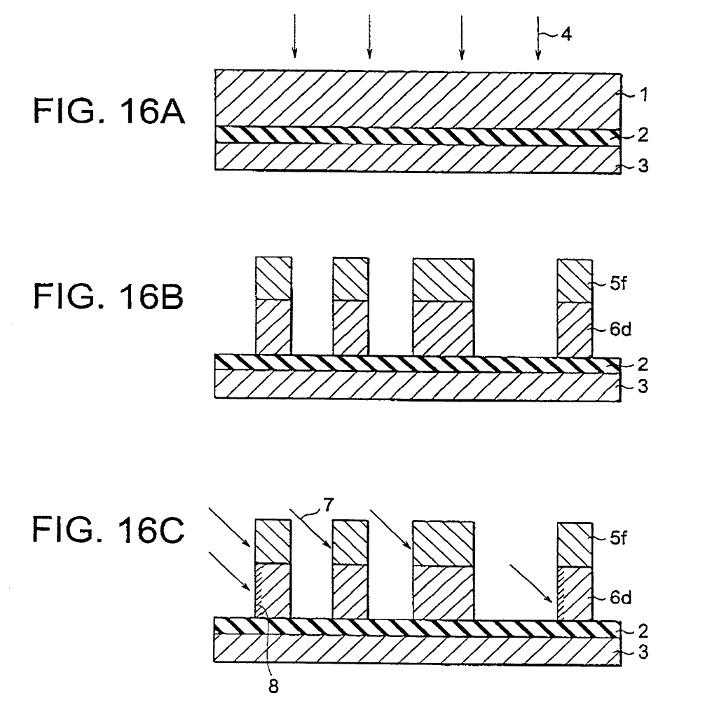

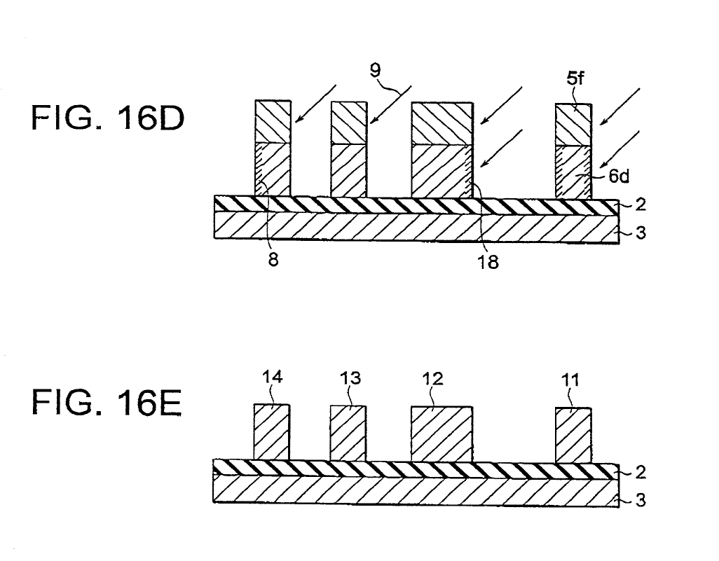

FIGS. 16A to 16E are sectional views showing a process for fabricating a semiconductor device according to a sixth embodiment of the present invention in the order of its steps. As shown in FIG. 16A, in the same manner as in the fourth embodiment, a silicon oxide film 2 is formed as an insulating film on a silicon substrate 3. Next, a poly-silicon film 1 is grown on the silicon oxide film 2. Thereafter, ion implantion (a fourth dose) 4 of boron is performed onto the whole surface.

Thereafter, as shown in FIG. 16B, the poly-silicon film 1 is patterned using a photoresist film 5f as a mask, to make poly-silicon film into poly-silicon pattern pieces 6d. In this case, a point different from the fourth embodiment is that the width of some poly-silicon pattern pieces 6d are different from that of the other pattern pieces.

Thereafter, as shown in FIG. 16C, in the same manner as in the fourth embodiment, in the state that the photoresist film 5f remains on the poly-silicon pattern pieces 6d, ion implantation (a first dose) 7 of boron is performed in the direction perpendicular to the longitudinal direction of the poly-silicon film pattern pieces 6d (from the left side in FIG. 16C), when viewed from the above, and at an angle of 45° in an obliquely upper direction to the surface of the silicon substrate 3. Thus, boron implanted areas 8 are formed.

As shown in FIG. 16D, in the same manner as in the fourth embodiment of the present invention, in the state that the photoresist 5f remains on the poly-silicon pattern pieces 6d, ion implantation (the first dose) 9 of boron is performed in the direction perpendicular to the longitudinal direction of the poly-silicon film pattern pieces 6d(from the right side in FIG. 16D), when viewed from the above, and at an angle of 45° in an obliquely upper and right direction to the surface of the silicon substrate 3.

Similarly to the above in the present embodiment, in the case that, about the respective poly-silicon pattern pieces 6d, the pattern pieces 6d have no pattern pieces at the adjacent pitch position on the right in FIG. 16D (the two poly-silicon pattern pieces 6d at the right side in FIG. 16D), boron is ion-implanted in the right side face of the pattern pieces 6d to form boron implanted areas 18. In the case that the poly-silicon pattern pieces 6d have other pattern pieces at the adjacent pitch position on the right in FIG. 16D (the two poly-silicon pattern pieces 6d at the left side in FIG. 16D), born is not ion-implanted in the right side of the pattern piece 6d by shadowing effect of the photoresist 5f on the adjacent pattern piece 6d.

Therefore, in the case of, for example, the right end pattern piece 6d in FIG. 16D (namely, in the case that any poly-silicon pattern piece is not present at pitch positions adjacent to both sides of the poly-silicon pattern piece 6d), boron is implanted in the first dose in both side faces of the piece 6d. In the case of, for example, the second piece 6d from the right end of FIG. 16D (namely, in the case that the piece 6d has, only at the left side pitch position adjacent thereto, another piece and does not have, at the right side pitch position adjacent thereto, any piece), boron is implanted in the first dose only in the right side of the piece 6d. In the case of, for example, the second piece 6d from the left end of FIG. 16D (namely, in the case that the piece 6d has, at both sides adjacent thereto, other pieces), boron is not implanted to both side faces of the piece 6d. In the case of, for example, the left end piece 6d in FIG. 16D (namely, in the case that the piece 6d has, only at the right side pitch position adjacent thereto, another piece and does not have, at the left side pitch position adjacent thereto, any piece), boron is implanted in the first dose only in the left side of the piece 6d.

The photoresist film 5f is removed and then annealing treatment is performed to diffuse boron. Thus, boron is activated. As a result, as shown in FIG. 16E, resistance elements having different sheet resistances (ρs) [that is, a resistance element (ρs1) 11, a resistance element (ρs2) 12, a resistance element (ρs5) 13 and a resistance element (ρs6) 14] are formed, correspondingly to the respective boron concentrations in the poly-silicon pattern pieces. In this case, boron is implanted into the second resistance element from the right end in FIG. 16E in the same dose as in the left end resistance element but the width of the former is larger than that of the latter. Therefore, the concentrations of boron diffused by the annealing are different so that the former and the latter have different sheet resistances.

In the manner as described above, the resistance elements having plural sheet resistances can be formed on the same substrate without addition of any mask. In the present embodiment, the same effect can be obtained by using impurities such as phosphorus, arsenic and antimony, as well as boron.

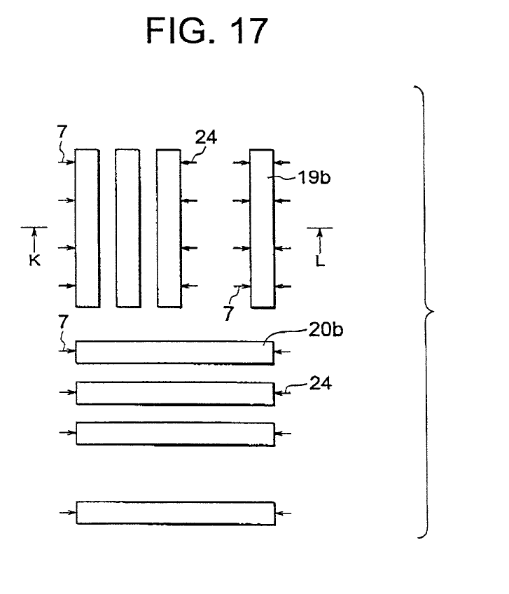

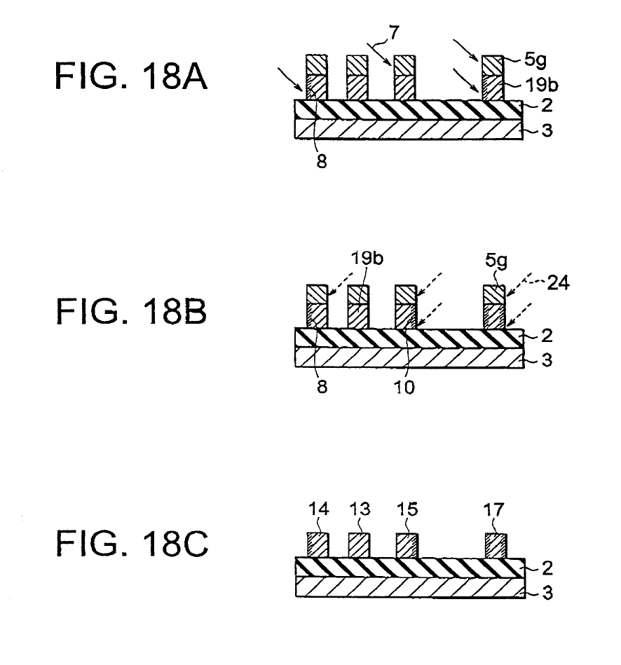

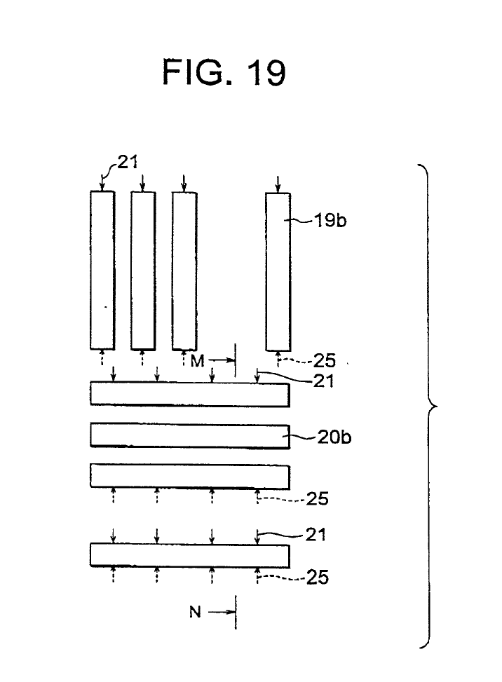

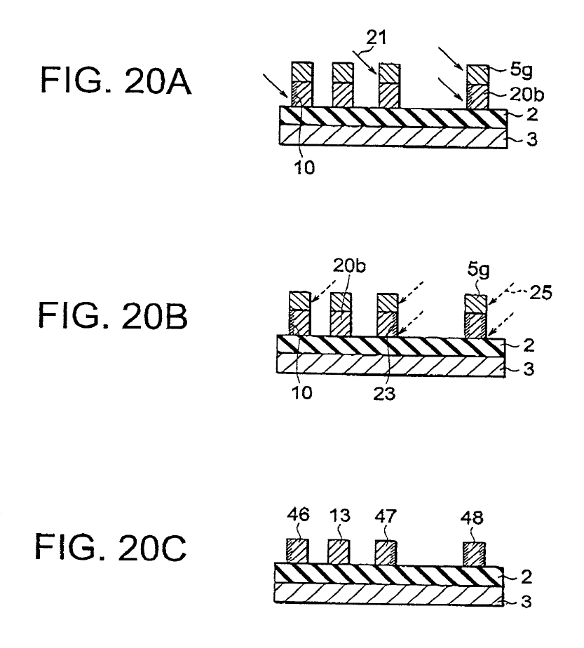

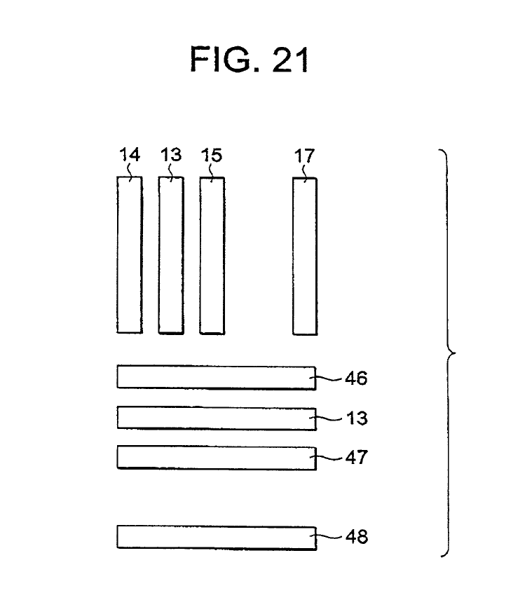

FIGS. 17 to 21 show a seventh embodiment of the present invention. FIGS. 17, 19 and 21 are plane views of a resistance element portion, which is viewed along the direction perpendicular to a silicon substrate and from the above. FIGS. 18A to 18C are sectional views taken along K-L line of FIG. 17, and FIGS. 20A to 20c are sectional views taken along M-N line of FIG. 19. A silicon oxide film 2 is formed on a silicon substrate 3. Poly-silicon pattern pieces 19b having a constant width are formed in one direction and in parallel on a silicon oxide film 2, and poly-silicon pattern pieces 20b having a constant width are formed in the direction perpendicular to the pieces 19b and in parallel.

In the same manner as in the second embodiment, in the present embodiment a silicon oxide film 2 is formed as an insulating film on a silicon substrate 3. Next, a poly-silicon film is grown. Thereafter, photolithographic technique is used to pattern the poly-silicon film. Thus, poly-silicon pattern pieces 19b and the poly-silicon pattern pieces 20b are simultaneously formed.

In the same manner as in the second embodiment, as shown in FIG. 18A, in the state that the mask of a photoresist film 5g remains on the poly-silicon film, ion implantation (a first dose) 7 of boron is performed onto one side face of each of the poly-silicon pattern pieces 19b in the direction perpendicular to the longitudinal direction of the poly-silicon pattern pieces 19 (from the left side in this figure), when viewed from the above, and at an angle of 45° in an obliquely upper and left direction to the silicon substrate 3. Furthermore, as shown in FIG. 18B, ion implantation (a fifth dose) 24 of boron is performed onto the other side face of each of the poly-silicon pattern pieces 19b at an angle of 45° in an obliquely upper and right direction to the silicon substrate 3. In this case, boron is ion-implanted only into side faces along short sides of each of the poly-silicon pattern pieces 20b.

Subsequently, in the same manner as in the second embodiment, oblique ion implantation (a second dose) 21 of boron is performed from the upper side in FIG. 19 and then oblique ion implantation (a sixth dose) 25 of boron is performed from the lower side in FIG. 19. similarly to the above, boron is ion-implanted only into side faces along short sides of each of the poly-silicon pattern pieces 19b.

Next, the photoresist film 5g is removed and then annealing treatment is performed to diffuse boron. As shown in FIGS. 18C, 20C and 21, in the same manner as in the fifth embodiment, boron is activated so that in the poly-silicon pattern pieces 19b, resistance elements having different sheet resistances (ρs) [that is, a resistance element (ρs8) 17, a resistance element (ρs7) 15, a resistance element (ρs5) 13 and a resistance element (ρs6) 14] are formed, correspondingly to the respective boron concentrations. Besides, in the poly-silicon pattern pieces 20b, resistance elements having different sheet resistances (ρs) [that is, a resistance element (ρs11) 48, a resistance element (ρs10) 47, a resistance element (ρs5) 13 and a resistance element (ρs9) 46] are formed, correspondingly to the respective boron concentrations.

In the above-mentioned manner, the resistance elements having 7 kinds of sheet resistances can be formed on the same substrate without addition of any mask. The same effect can be obtained by using phosphorus, arsenic, antimony or the like, as well as boron, as the impurity in 20 the present embodiment.

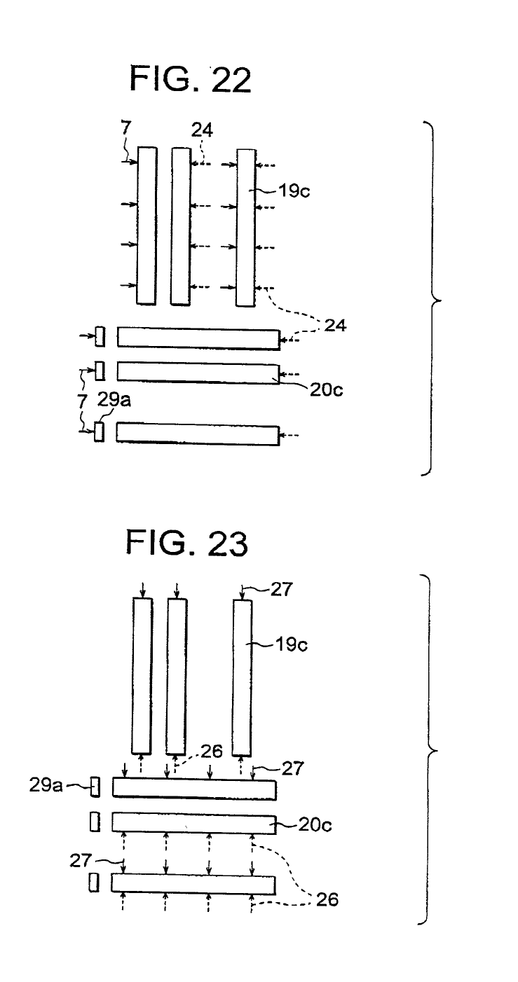

FIGS. 22 to 24 are views for explaining an eighth embodiment of the present invention, and are plane views for a resistance element portion, which is viewed along the direction perpendicular to a silicon substrate and from the above. In the same manner as in the seventh embodiment, a silicon oxide film is formed as an insulating film on a silicon substrate. Next, a poly-silicon film is grown.

Thereafter, photolithographic technique is used to pattern the poly-silicon film. Thus, poly-silicon pattern pieces 19c and the poly-silicon pattern pieces 20c are simultaneously formed.

In this case, poly-silicon dummy pattern pieces 29a may be formed near side faces along short sides of each of the poly-silicon pattern pieces 20c in the same manner as in the third embodiment.

As shown in FIG. 22 in the same manner as in the seventh embodiment, oblique ion implantation of boron is performed into the poly-silicon pattern pieces 19c and then, as shown in FIG. 23 in the same manner as in the third embodiment, oblique ion implantation of arsenic is performed into the poly-silicon pattern pieces 20c.

As shown in FIG. 24 subsequently, the photoresist film is removed and then annealing treatment is performed to diffuse and activate boron and arsenic. In this way, in the poly-silicon pattern pieces 19c, a P type poly-silicon resistance element (ρs6) 30, a P type resistance element (ρs7) 31 and a P type resistance element (ρs8) 32 are formed, correspondingly to the respective boron concentrations. Besides, in the poly-silicon pattern pieces 20c, an N type resistance element (ρs12) 33, an N type resistance element (ρs13) 34 and an N type resistance element (ρs14) 35] are formed, correspondingly to the respective arsenic concentrations. In this case, resistance elements along the same direction as the poly-silicon pattern pieces 19c are arranged have a P type conduction type and three kinds of sheet resistances, and resistance elements along the same direction as the poly-silicon pattern pieces 20c are arranged have an N type conduction type and three types of sheet resistances.

As described above, according to the present embodiment, resistance elements having two types of conduction types, the two resistance elements each having 3 types of sheet resistances, can be formed on the same substrate without addition of any mask. The same effect can be obtained by using phosphorus, arsenic, antimony or the like, as well as boron and arsenic, as the impurity in the present embodiment.

As described above in detail, according to the present invention, in the implantation of impurities for deciding sheet resistances of resistance elements, a photoresist for patterning the resistance elements is used to ion-implant the impurities into side faces from the oblique upper just after the patterning without using additional exclusive mask pattern. In this way, shadowing effect of the photoresist, based on the difference in the arrangement pattern of the resistance elements, is used to optimize the angle and the direction of the ion implantation. As a result, the amounts of the impurities implanted into the respective resistance elements can be controlled. Therefore, the resistance elements having plural sheet resistances can be formed on the same substrate in fewer steps. Thus, according to the present invention, it is unnecessary to add any photolithographic step for forming resistance elements having plural sheet resistances. As a result, semiconductor-fabricating steps can be shortened.

What is claimed is:

1. A semiconductor device having a resistance element comprising:
a resistance element pattern having resistance elements which have different widths and formed in one direction on a semiconductor substrate through an insulating film, sheet resistances (ρs) of the resistance elements having a correlation with the widths of the resistance elements and being different in accordance with the widths of the resistance elements.

2. A semiconductor device having a resistance element comprising:
a first resistance element pattern having resistance elements formed in one direction on a semiconductor substrate through an insulating film; and
a second resistance element pattern having resistance elements arranged in the direction perpendicular to the one direction, sheet resistances (ρs) of the respective resistance elements of the first resistance element pattern being different from sheet resistances (ρs) of the respective resistance elements of the second resistance element pattern.

3. A semiconductor device having a resistance element comprising:
a first resistance element pattern having resistance elements formed in one direction on a semiconductor substrate through an insulating film; and
a second resistance element pattern having resistance elements arranged in the direction perpendicular to the one direction, the conduction type of the respective resistance elements of the first resistance element pattern being different from the conduction type of the respective resistance elements of the second resistance element pattern.

4. A semiconductor device having a resistance element comprising:
a resistance element pattern having resistance elements formed in one direction on a semiconductor substrate through an insulating film, the sheet resistance (ρs) of a first resistance element having, at the nearest pitch positions on both sides thereof, the resistance elements, the sheet resistance (ρs) of a second resistance element having, only at the nearest pitch position on one side thereof, the resistance element, and the sheet resistance (ρs) of a third resistance element having, at the nearest pitch positions on both sides thereof, none of the resistance elements being different from each other.

5. A semiconductor device having a resistance element comprising;
a resistance element pattern having resistance elements formed in one direction on a semiconductor substrate through an insulating film, the sheet resistance (ρs) of a first resistance element having, at the nearest pitch positions on both sides thereof, the resistance elements, the sheet resistance (ρs) of a fourth resistance element having, only at the nearest pitch position on one specified side thereof, the resistance element, the sheet resistance (ρs) of a fifth resistance element having, only at the nearest pitch position on the other side opposite to the specified side, the resistance element, and the sheet resistance (ρs) of a third resistance element having, at the nearest pitch positions on both sides thereof, none of the resistance elements being different from each other.

6. A semiconductor device having a resistance element comprising:
a resistance element pattern having resistance elements formed in one direction on a semiconductor substrate through an insulating film, the sheet resistance (ρs) of a sixth resistance element having, on both sides thereof, the resistance elements arranged at a given minimum interval, the sheet resistance (ρs) of a seventh resistance element having, on one specified side thereof, the resistance element arranged at the minimum interval and, on the other side opposite to the specified side, the resistance element arranged at not less than the minimum interval, and having the same width as the sixth resistance element, the sheet resistance (ρs) of an eighth resistance element having, on one specified side thereof, the resistance element arranged at not less than the minimum interval and, on the other side opposite to the specified side, the resistance element arranged at the minimum interval, and having the same width as the sixth resistance element, the sheet resistance (ρs) of a ninth resistance element having, on both sides thereof, the resistance elements arranged at not less than the minimum interval, and having the same width as the sixth resistance element, the sheet resistance (ρs) of a tenth resistance element having, on both sides thereof, the resistance elements arranged at the minimum interval, and having a width different from that of the sixth resistance element, the sheet resistance (ρs) of an eleventh resistance element having, on one specified side thereof, the resistance element arranged at the minimum interval and, on the other side opposite to the specified side, the resistance element arranged at not less than the minimum interval, and having a width different from that of the seventh resistance element, the sheet resistance (ρs) of a twelfth resistance element having, on one specified side thereof, the resistance element arranged at not less than the minimum interval and, on the other side opposite to the specified side, the resistance element arranged at the minimum interval, and having a width different from that of the eighth resistance element, and the sheet resistance (ρs) of a thirteenth resistance element having, on both sides thereof, the resistance elements arranged at not less than the minimum interval, and having a width different from that of the ninth resistance element being different from each other.

7. A semiconductor device having a resistance element comprising:
a first resistance element pattern having resistance elements A formed in one direction on a semiconductor substrate through an insulating film; and
a second resistance element pattern having resistance elements B arranged in the direction perpendicular to the one direction, the sheet resistance (ρs) of a first resistance element A having, at the nearest pitch positions on both sides thereof, the resistance elements A, the sheet resistance (ρs) of a second resistance element A having, at the nearest pitch position on only one side thereof, the resistance element and having, at the nearest pitch position on the other side opposite to the one side, no resistance element A, the sheet resistance (ρs) of a third resistance element A having, at the nearest pitch positions on both sides thereof, none of the resistance elements A, the sheet resistance (ρs) of a first resistance element B having, at the nearest pitch position on only one side thereof, the resistance element B and having, at the nearest pitch position on the other side opposite to the one side, no resistance element B, and the sheet resistance (ρs) of a second resistance element B having, at the nearest pitch positions on both sides thereof, none of the resistance elements B being different from each other.

8. A semiconductor device having a resistance element comprising:
a first resistance element pattern having resistance elements A formed in one direction on a semiconductor substrate through an insulating film; and
a second resistance element pattern having resistance elements B arranged in the direction perpendicular to the one direction, the sheet resistance (ρs) of a first resistance element A having, at the nearest pitch positions on both sides thereof, the resistance elements A, the sheet resistance (ρs) of a fourth resistance element A having, at the nearest pitch position on only one specified side thereof, the resistance element A and having, at the nearest pitch position on the other side opposite to the one side, no resistance element A, the sheet resistance (ρs) of a fifth resistance element A having, at the nearest pitch position on only the other side opposite to the specified side thereof, the resistance element A, the sheet resistance (ρs) of a third resistance element A having, at the nearest pitch positions on both sides thereof, none of the resistance elements A, the sheet resistance (ρs) of a third resistance element B having, at the nearest pitch position on only one specified side thereof, the resistance element B, the sheet resistance (ρs) of a fourth resistance element B having, at the nearest pitch position on only the other side opposite to the specified side thereof, the resistance element B, and the sheet resistance (ρs) of a second resistance element B having, at the nearest pitch positions on both sides thereof, none of the resistance elements B being different from each other.

9. A semiconductor device having a resistance element comprising:
a resistance element pattern having resistance elements E formed in one direction on a semiconductor substrate through an insulating film; and
a second resistance element pattern having resistance elements E arranged in the direction perpendicular to the one direction, the sheet resistance (ρs) of a first resistance element E having, on both sides thereof, the resistance elements E arranged at a given minimum interval, the sheet resistance (ρs) of a second resistance element E having, on one specified side thereof, the resistance element E arranged at the minimum interval and, on the other side opposite to the specified side, the resistance element arranged at not less than the minimum interval, and having the same width as the first resistance element E, the sheet resistance (ρs) of a third resistance element having, on one specified side thereof, the resistance element E arranged at not less than the minimum interval and, on the other side opposite to the specified side, the resistance element E arranged at the minimum interval, and having the same width as the first resistance element E, the sheet resistance (ρs) of a fourth resistance element E having, on both sides thereof, the resistance elements E arranged at not less than the minimum interval, and having the same width as the first resistance element E, the sheet resistance (ρs) of a fifth resistance element E having, on both sides thereof, the resistance elements E arranged at the minimum interval, and having a width different from that of the first resistance element E, the sheet resistance (ρs) of a sixth resistance element having, on one specified side thereof, the resistance element E arranged at the minimum interval and, on the other side opposite to the specified side, the resistance element E arranged at not less than the minimum interval, and having a width different from that of the second resistance element E, the sheet resistance (ρs) of a seventh resistance element E having, on one specified side thereof, the resistance element E arranged at not less than the minimum interval and, on the other side opposite to the specified side, the resistance element E arranged at the minimum interval, and having a width different from that of the third resistance element E, the sheet resistance (ρs) of an eighth resistance element E having, on both sides thereof, the resistance elements E arranged at not less than the minimum interval, and having a width different from that of the fourth resistance element E, the sheet resistance (ρs) of a first resistance element F having, on one specified side thereof, the resistance element F arranged at the minimum interval and, on the other side opposite to the specified side, the resistance element F arranged at not less than the minimum interval, the sheet resistance (ρs) of a second resistance element F having, on one specified side thereof, the resistance element F arranged at the minimum interval and, on the other side opposite to the specified side, the resistance element F arranged at not less than the minimum interval, and having the same width as the first resistance element F, the sheet resistance (ρs) of a third resistance element F having, on one specified side thereof, the resistance element F arranged at not less than the minimum interval and, on the other side opposite to the specified side, the resistance element F arranged at the minimum interval, and having the same width as the first resistance element F, the sheet resistance (ρs) of a fourth resistance element F having, on both sides thereof, the resistance elements F arranged at not less than the minimum interval, and having the same width as the first resistance element F, the sheet resistance (ρs) of a fifth resistance element F having, on one specified side thereof, the resistance element F arranged at the minimum interval and, on the other side opposite to the specified side, the resistance element F arranged at not less than the minimum interval, and having a width different from that of the first resistance element F, the sheet resistance (ρs) of a sixth resistance element F having, on one specified side thereof, the resistance element F arranged at not less than the minimum interval and, on the other side opposite to the specified side, the resistance element F arranged at the minimum interval, and having a width different from that of the second resistance element F, the sheet resistance (ρs) of a seventh resistance element F having, on both sides thereof, the resistance elements F arranged at not less than the minimum interval, and having a width different from that of the third resistance element F being different from each other.

10. A semiconductor device having a resistance element comprising:
a first resistance element pattern having resistance elements G of a first conduction type formed in one direction on a semiconductor substrate through an insulating film; and
a second resistance element pattern having resistance elements H of a second conduction type arranged in the direction perpendicular to the one direction,
The sheet resistance (ρs) of a first resistance element G having, at the nearest pitch position on only one 5 side thereof, the resistance element G and having, at the nearest pitch position on the other side opposite to the one side, no resistance element G, and the sheet resistance (ρs) of a second resistance element G having, at the nearest pitch positions on both sides thereof, none of the resistance elements G being different from each other, and,
the sheet resistance (ρs) of a first resistance element H having, at the nearest pitch position on only one side thereof, the resistance element E and having, at the nearest pitch position on the other side opposite to the one side, no resistance element H, and the sheet resistance (ρs) of a second resistance element E having, at the nearest pitch positions on both sides thereof, none of the resistance elements H being different from each other.

11. A semiconductor device having a resistance element comprising:
a first resistance element pattern having resistance elements G of a first conduction type are formed in one direction and on a semiconductor substrate through an insulating film; and
a second resistance element pattern having resistance elements E of a second conduction type arranged in the direction perpendicular to the one direction,
the sheet resistance (ρs) of a third resistance element G having, at the nearest pitch position on only one specified side thereof, the resistance element G and having, at the nearest pitch position on the other side opposite to the one side, no resistance element G, the sheet resistance (ρs) of a fourth resistance element G having, at the nearest pitch position on one specified side thereof, no resistance element G and having, at the nearest pitch position on only the other side opposite to the specified side thereof, the resistance element G, and the sheet resistance (ρs) of a second resistance element G having, at the nearest pitch positions on both sides thereof, none of the resistance elements G being different from each other, and
the sheet resistance (ρs) of a third resistance element H having, at the nearest pitch position on only one specified side thereof, the resistance element G and having, at the nearest pitch position on the other side opposite to the one side, no resistance element H, the sheet resistance (ρs) of a fourth resistance element G having, at the nearest pitch position on one specified side thereof, no resistance element H and having, at the nearest pitch position on only the other side opposite to the specified side thereof, the resistance element H, and the sheet resistance (ρs) of a second resistance element E having, at the nearest pitch positions on both sides thereof, none of the resistance elements H being different from each other.

12. The semiconductor device having a resistance element according to claim 1, the resistance element being fabricated by performing ion-implantation into a pattern of a poly-silicon film in a direction inclined to the semiconductor substrate.

13. A process for fabricating a semiconductor device having a resistance element comprising the steps of:
growing a poly-silicon film on an insulating substrate;
forming a pattern of a photoresist;
using the photoresist pattern as a mask to pattern the poly-silicon film by photolithographic technique and etching, thereby forming a resistance element pattern comprising plural resistance elements arranged in one direction; and
ion-implanting an impurity, in a direction perpendicular to side faces of the resistance elements and at an angle in an oblique upper direction to the substrate, into side faces of the resistance elements, in the state that the photoresist remains on the resistance elements.

14. The process according to claim 13, wherein the resistance element pattern has a narrow pattern piece in which ions are not implanted into its side face in the ion implanting step by shield with the photoresist on the resistance element adjacent thereto, and a wide pattern piece in which ions are implanted into its side face in the ion implanting step without shield with the photoresist on the resistance element adjacent thereto.

15. The process according to claim 13, wherein some of the resistance elements have a width different from that of the other resistance elements in the resistance element pattern .
